(19) United States
(12) Patent Application Publication
(10) Pub. No.: US 2026/0269114 A1
(43) Pub. Date: Sep. 10, 2026

(54) MAGNET MODULE, SENSOR MODULE, AND METHOD FOR MANUFACTURING MAGNET MODULE

(71) Applicant: Panasonic Intellectual Property Management Co., Ltd., Osaka (JP)

(72) Inventors: Kazuhiro ONAKA, Hyogo (JP); Noritaka ICHINOMIYA, Nara (JP)

(21) Appl. No.: 18/993,438

(22) PCT Filed: Jul. 26, 2023
(86) PCT No.: PCT/JP2023/027333

§ 371 Date: Jan. 10, 2025

(30) Foreign Application Priority Data
Jul. 29, 2022 (JP) 2022-121620

(51) Int. Cl. H01F 7/02; H01F 13/00; H01F 41/02

(52) U.S. Cl. CPC H01F 7/0294; H01F 7/0221; H01F 13/003; H01F 41/0253

(57) ABSTRACT

A magnet module is designed for use in a magnetic sensor. The magnetic sensor outputs a signal representing a detected magnetic field. The magnet module includes a first magnet and a second magnet. The first magnet and the second magnet are both magnetized in a first direction and a second direction. The first magnet and the second magnet are provided separately and coupled to each other in a third direction to have mutually different magnetization directions.

### TECHNICAL FIELD

The present disclosure generally relates to a magnet module, a sensor module, and a method for manufacturing the magnet module, and more particularly relates to a magnet module for use in a magnetic sensor, a sensor module, and a method for manufacturing such a magnet module.

### BACKGROUND ART

Patent Literature 1 discloses a magnetic sensor device including a first bias magnet, a second bias magnet, and a magnetic sensor. The second bias magnet is arranged to form a predetermined angle with respect to the first bias magnet. The magnetic sensor is interposed between a bottom surface of the first bias magnet and an upper surface of the second bias magnet.

### CITATION LIST

### Patent Literature

Patent Literature 1: JP 2017-173236 A

### SUMMARY OF INVENTION

A magnetic sensor device such as the one disclosed in Patent Literature 1 is increasingly required to position a magnetic body (as a detection target) more accurately.

An object of the present disclosure is to provide a magnet module, a sensor module, and a method for manufacturing the magnet module, all of which contribute to positioning a detection target more accurately.

A magnet module according to an aspect of the present disclosure is designed for use in a magnetic sensor. The magnetic sensor outputs a signal representing a detected magnetic field. The magnet module includes a first magnet and a second magnet. The first magnet and the second magnet are both magnetized in a first direction and a second direction. The second direction is perpendicular to the first direction. The first magnet and the second magnet are provided separately and coupled to each other in a third direction to have mutually different magnetization directions. The third direction is perpendicular to the first direction and the second direction.

A sensor module according to another aspect of the present disclosure includes the magnet module described above; the magnetic sensor described above; and a sensor-covering resin member. The sensor-covering resin member covers the magnet module and the magnetic sensor.

A method for manufacturing a magnet module according to still another aspect of the present disclosure is method for manufacturing a magnet module for use in a magnetic sensor. The magnetic sensor outputs a signal representing a detected magnetic field. The method for manufacturing the magnet module includes a producing step and a coupling step. The producing step includes producing a first magnet and a second magnet by magnetizing a magnetic material in a first direction and a second direction. The second direction is perpendicular to the first direction. The coupling step includes coupling the first magnet and the second magnet to each other in a third direction to cause the first magnet and the second magnet to have mutually different magnetization directions. The third direction is perpendicular to both the first direction and the second direction.

### BRIEF DESCRIPTION OF DRAWINGS

FIG. 1A is a front view of a magnet module according to a first embodiment;

FIG. 1B is a side view of the magnet module;

FIG. 2A is a front view of a first magnet of the magnet module;

FIG. 2B is a side view of the first magnet;

FIG. 3A is a front view of a second magnet of the magnet module;

FIG. 3B is a side view of the second magnet;

FIG. 4 is a schematic representation illustrating a magnetization method for the magnet module;

FIG. 5 is a flowchart showing a method for manufacturing the magnet module;

FIG. 6 is a front view of a magnet module according to a second embodiment;

FIG. 7A is a front view of a magnet module according to a third embodiment;

FIG. 7B is a side view of the magnet module;

FIG. 8A is a front view of a sensor module according to a fourth embodiment; and

FIG. 8B is a side view of the sensor module.

### DESCRIPTION OF EMBODIMENTS

First to fourth embodiments of a magnet module, a sensor module, and a method for manufacturing a magnet module will be described with reference to the accompanying drawings. The drawings to be referred to in the following description of the first to fourth embodiments are all schematic representations. Thus, the ratio of the dimensions (including thicknesses) of respective constituent elements illustrated on the drawings does not always reflect their actual dimensional ratio. Note that the configurations to be described below for the first to fourth embodiments are only examples of the present disclosure and should not be construed as limiting. Rather, the first to fourth exemplary embodiments may be readily modified in various manners depending on a design choice or any other factor without departing from the scope of the present disclosure.

As used herein, if two things “are perpendicular to each other (or cross each other at right angles),” this expression refers to not only a situation where the angle formed between the two things is exactly 90 degrees but also a situation where the angle formed between the two things is not 90 degrees and the difference of the angle formed between the two things from 90 degrees falls within a predetermined range (e.g., ±10 degrees). Likewise, as used herein, if something is “parallel to” something else, this expression refers to not only a situation where these two things never intersect with each other in a strict sense of the word but also a situation where the angle formed between these two things falls within a predetermined range (e.g., ±10 degrees) of difference.

### First Embodiment

(1) Overview

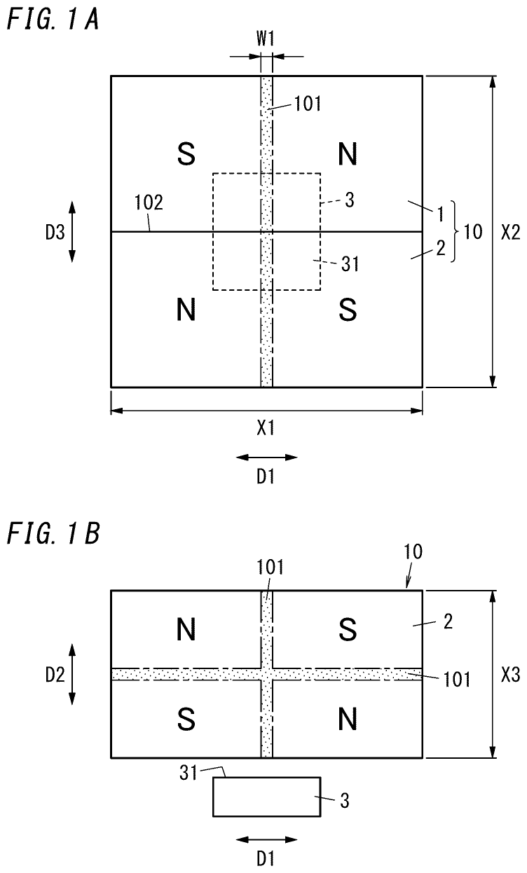

First, an overview of a magnet module 10 according to a first embodiment will be described with reference to FIGS. 1A-3B.

A magnet module 10 according to the first embodiment may be used, for example, in a motor along with a magnetic sensor 3. The motor may be used, for example, to adjust the focus of a camera (camera module) built in a mobile device such as a smartphone. The motor may be, for example, a voice coil motor (VCM). In the first embodiment, a detection target for the magnetic sensor 3 is a motor.

That is to say, the magnet module 10 is designed for use in the magnetic sensor 3. The magnetic sensor 3 outputs a signal (e.g., a voltage signal) representing a detected magnetic field. In the first embodiment, the magnet module 10 is a bias magnet. That is to say, the magnet module 10 is a magnet for generating a bias magnetic field with respect to the magnetic sensor 3.

The magnet module 10 according to the first embodiment includes a first magnet 1 and a second magnet 2 as shown in FIGS. 1A-3B. The first magnet 1 and the second magnet 2 are both magnetized in a first direction D1 and a second direction D2. The second direction D2 is perpendicular to the first direction D1. The first magnet 1 and the second magnet 2 are provided separately and coupled to each other in a third direction D3 to have mutually different magnetization directions. The third direction D3 is perpendicular to the first direction D1 and the second direction D2.

In the magnet module 10 according to the first embodiment, the first magnet 1 and the second magnet 2 are coupled to each other in the third direction D3 to have mutually different magnetization directions. This may reduce, in the third direction D3, a neutral zone 102 to be produced between the first magnet 1 and the second magnet 2, thus enabling increasing a bias magnetic field to be applied by the magnet module 10 to the magnetic sensor 3. This allows the magnetic sensor 3 to have improved detection accuracy, thus contributing to positioning the detection target (such as a motor) more accurately.

### (2) Details

Next, a configuration for the magnet module 10 according to the first embodiment will be described with reference to FIGS. 1A-3B. In the following description, the longitudinal axis of each of the first magnet 1 and the second magnet 2 is defined to be the first direction D1, their thickness axis is defined to be the second direction D2, and their latitudinal axis (i.e., their width axis) is defined to be the third direction D3. Note that these definitions should not be construed as limiting the directions in which the first magnet 1 and the second magnet 2 are supposed to be used. In addition, these directions are just shown on the drawings for illustrative purposes only and are all insubstantial ones.

The magnet module 10 according to the first embodiment is designed for use in the magnetic sensor 3, for example, as described above. The magnet module 10 may be, for example, a bias magnet. That is to say, the magnet module 10 is a magnet for generating a bias magnetic field with respect to the magnetic sensor 3. In short, the first magnet 1 and second magnet 2 included in the magnet module 10 generate a bias magnetic field with respect to the magnetic sensor 3.

The magnet module 10 includes the first magnet 1 and the second magnet 2 as shown in FIGS. 1A and 1B. In the magnet module 10 according to the first embodiment, the first magnet 1 and the second magnet 2 are provided separately from each other. Each of the first magnet 1 and the second magnet 2 is a double-sided, four-pole magnet.

### (2.1) First Magnet

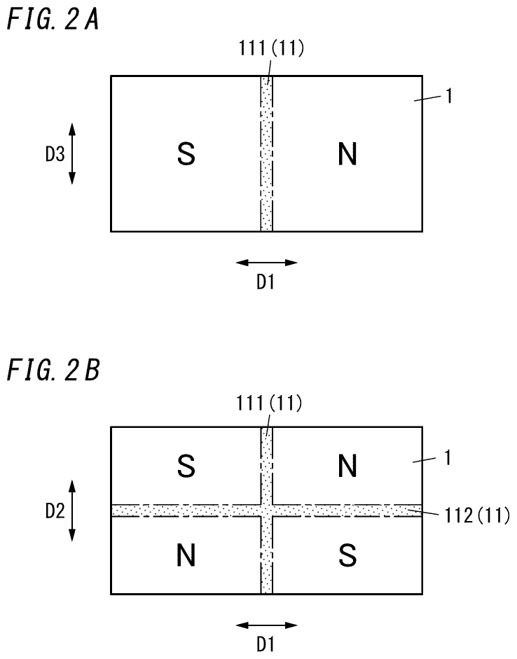

The first magnet 1 may be, for example, a neodymium magnet. The first magnet 1 has a rectangular parallelepiped shape, as shown in FIGS. 2A and 2B. As shown in FIG. 2A, when viewed in plan in the second direction D2, the first magnet 1 has the shape of a rectangle which is longer in the first direction D1 rather than in the third direction D3. As shown in FIG. 2B, when viewed in plan in the third direction D3, the first magnet 1 has the shape of a rectangle which is longer in the first direction D1 rather than in the second direction D2.

In the first embodiment, when viewed in plan in the second direction D2, the first magnet 1 has been magnetized to have an S-pole and an N-pole from left to right as shown in FIG. 2A. In addition, in the first embodiment, when viewed in plan in the third direction D3, the first magnet 1 has been magnetized to have an N-pole opposite from (i.e., under in FIG. 2B) the S-pole and have an S-pole opposite from (i.e., under in FIG. 2B) the N-pole as shown in FIG. 2B. That is to say, the first magnet 1 has been magnetized in the first direction D1 and the second direction D2 perpendicular to the first direction D1.

The first magnet 1 that has been magnetized as described above has a plurality of neutral zones 11. The plurality of neutral zones 11 includes a first neutral zone 111 and a second neutral zone 112. The first neutral zone 111 is interposed, when viewed in plan in the second direction D2, between the S-pole and the N-pole which are arranged in line in the first direction D1. The second neutral zone 112 is interposed, when viewed in plan in the third direction D3, between the S-and N-poles which are arranged in line in the second direction D2.

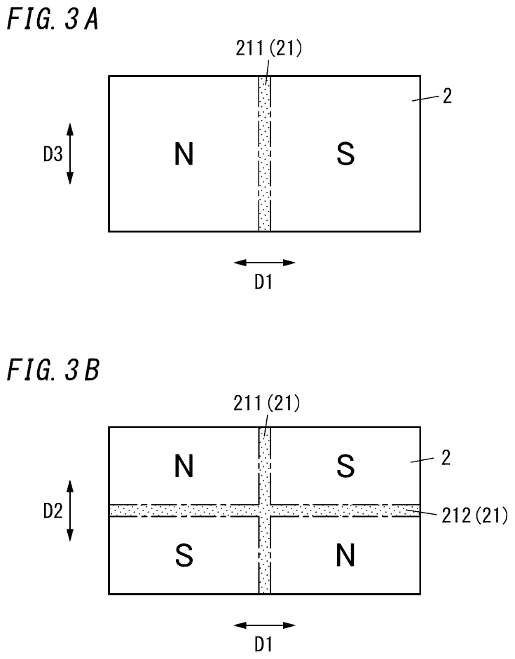

As used herein, the “neutral zone” refers to a part located between an S-pole and an N-pole where the polarity switches from the S-pole to the N-pole, and vice versa, and is a part located between an interface, facing the N-pole, of the S-pole and an interface, facing the S-pole, of the N-pole. That is to say, neither the first neutral zone 111 nor the second neutral zone 112 has been magnetized to have an S-pole or an N-pole. Note that in FIGS. 2A and 2B, the first neutral zone 111 and the second neutral zone 112 are shaded with dotted hatching to be easily distinguishable from the rest of the first magnet 1 but the dotted hatching does not indicate a cross section. The same statement is applicable to FIGS. 1A, 1B, 3A, and 3B.

### (2.2) Second Magnet

The second magnet 2, as well as first magnet 1, may be, for example, a neodymium magnet. The second magnet 2 has a rectangular parallelepiped shape, as shown in FIGS. 3A and 3B. As shown in FIG. 3A, when viewed in plan in the second direction D2, the second magnet 2 has the shape of a rectangle which is longer in the first direction D1 rather than in the third direction D3. As shown in FIG. 3B, when viewed in plan in the third direction D3, the second magnet 2 has the shape of a rectangle which is longer in the first direction D1 rather than in the second direction D2. In the first embodiment, the first magnet 1 and the second magnet 2 have the same dimensions.

In the first embodiment, when viewed in plan in the second direction D2, the second magnet 2 has been magnetized to have an N-pole and an S-pole from left to right as shown in FIG. 3A. In addition, in the first embodiment, when viewed in plan in the third direction D3, the second magnet 2 has been magnetized to have an S-pole opposite from (i.e., under in FIG. 3B) the N-pole and have an N-pole opposite from (i.e., under in FIG. 3B) the S-pole as shown in FIG. 3B. That is to say, the second magnet 2 has been magnetized in the first direction D1 and the second direction D2 perpendicular to the first direction D1.

The second magnet 2 that has been magnetized as described above has a plurality of neutral zones 21. The plurality of neutral zones 21 includes a first neutral zone 211 and a second neutral zone 212. The first neutral zone 211 is interposed, when viewed in plan in the second direction D2, between the N-pole and the S-pole which are arranged in line in the first direction D1. The second neutral zone 212 is interposed, when viewed in plan in the third direction D3, between the N-and S-poles which are arranged in line in the second direction D2.

### (2.3) Magnet Module

In the first embodiment, the magnet module 10 is produced by coupling the first magnet 1 and the second magnet 2 to each other. More specifically, as shown in FIG. 1A, the first magnet 1 and the second magnet 2 are coupled to each other in the third direction D3 to make the magnetization direction of the first magnet 1 and the magnetization direction of the second magnet 2 different from each other. In other words, the first magnet 1 and the second magnet 2 are coupled to each other to make the magnetic pole of the first magnet 1 and the magnetic pole, facing the magnetic pole of the first magnet 1, of the second magnet 2 opposite from each other in the third direction D3. In this case, the first magnet 1 and the second magnet 2 are coupled to each other by magnetic attraction produced between the first magnet 1 and the second magnet 2. As used herein, the expression “the first magnet and the second magnet are coupled to each other” refers to both a situation where the first magnet and the second magnet are directly coupled to each other and a situation where the first magnet and the second magnet are indirectly coupled to each other via another member (such as a bonding member 4 (to be described later)).

As shown in FIGS. 1A and 1B, the magnet module 10 has a plurality of (e.g., two in the example shown in FIGS. 1A and 1B) first neutral zones 101 and a second neutral zone 102. Each of the plurality of first neutral zones 101 is a neutral zone provided for each of the first magnet 1 and the second magnet 2. The second neutral zone 102 is a neutral zone provided between the first magnet 1 and the second magnet 2 when the first magnet 1 and the second magnet 2 are coupled to each other. In the first embodiment, the second neutral zone 102 has a width of 0 mm as shown in FIG. 1A. Thus, when viewed in plan in the second direction D2, the width of the second neutral zone 102 provided between the first magnet 1 and the second magnet 2 is narrower than the width W1 of the first neutral zone 101 in each of the first magnet 1 and the second magnet 2.

In addition, the magnet module 10 may have, for example, a rectangular parallelepiped shape as shown in FIGS. 1A and 1B. The dimension X1 of the magnet module 10 as measured in the first direction D1 may be 5 mm, for example. The dimension X2 of the magnet module 10 as measured in the third direction D3 may be 5 mm, for example. The dimension X3 of the magnet module 10 as measured in the second direction D2 may be 1 mm, for example. The magnet module 10 preferably has a dimension X1 equal to or less than 5 mm as measured in the first direction D1 and a dimension X2 equal to or less than 5 mm as measured in the third direction D3. This contributes to reducing the size of the magnet module 10.

In the first embodiment, the magnet module 10 is arranged in line with the magnetic sensor 3 in the second direction D2. A surface, facing the magnet module 10 (i.e., an upper surface in FIG. 1B), of the magnetic sensor 3 is a magnetically sensitive surface 31.

### (3) Magnetization Method

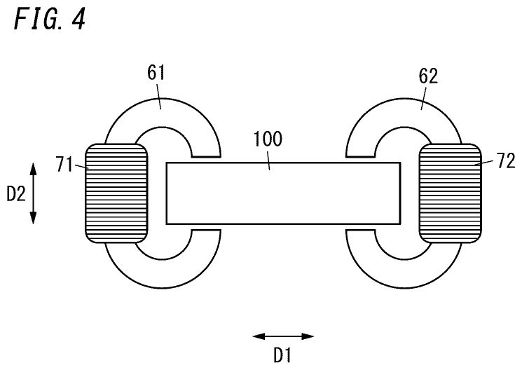

Next, a magnetization method for the first magnet 1 and the second magnet 2 will be described with reference to FIG. 4.

First, yokes 61, 62 are respectively fixed at both ends of a magnetic material 100 in the first direction D1. In this embodiment, the magnetic material 100 is a metallic compound containing, as main components thereof, neodymium, iron, and boron, for example. A coil 71 is wound around the yoke 61. On the other hand, a coil 72 is wound around the yoke 62.

Then, letting a current flow through the coils 71, 72 causes the magnetic material 100 to be magnetized via the yokes 61, 62, thus producing the first magnet 1 and the second magnet 2. In this case, making the direction of the current to flow through the coil 71 opposite from the direction of the current to flow through the coil 72 allows the magnetic material 100 to be magnetized in both the first direction D1 and the second direction D2. In this case, the width of the neutral zones 11, 21 may be narrowed by increasing the amount of current to flow through the coils 71, 72. In addition, the width of the neutral zones 11, 21 may also be narrowed by increasing the areas of contact of the yokes 61, 62 with the magnetic material 100.

Note that the first magnet 1 and the second magnet 2 to be magnetized by this magnetization method may have the same magnetization direction or two different magnetization directions, whichever is appropriate. In any case, the magnet module 10 may be produced by coupling the first magnet 1 and the second magnet 2 to each other to make their magnetization directions different from each other.

### (4) Method for Manufacturing Magnet Module

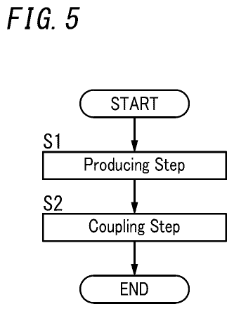

Next, a method for manufacturing the magnet module 10 according to the first embodiment will be described with reference to FIG. 5.

A method for manufacturing a magnet module 10 according to the first embodiment is method for manufacturing a magnet module 10 for use in a magnetic sensor 3. The magnetic sensor 3 outputs a signal (e.g., a voltage signal) representing a detected magnetic field. The method for manufacturing the magnet module 10 includes a producing step S1 and a coupling step S2. The producing step S1 includes producing a first magnet 1 and a second magnet 2 by magnetizing a magnetic material 100 (refer to FIG. 4) in a first direction D1 and a second direction D2. The coupling step S2 includes coupling the first magnet 1 and the second magnet 2 to each other in a third direction D3 to cause the first magnet 1 and the second magnet 2 to have mutually different magnetization directions.

In the method for manufacturing a magnet module 10 according to the first embodiment, the coupling step S2 includes coupling the first magnet 1 and the second magnet 2 to each other in the third direction D3 to cause the first magnet 1 and the second magnet 2 to have mutually different magnetization directions. This may reduce, in the third direction D3, the neutral zone 102 (refer to FIG. 1A) to be produced between the first magnet 1 and the second magnet 2, thus enabling increasing a bias magnetic field to be applied by the magnet module 10 to the magnetic sensor 3. This allows the magnetic sensor 3 to have improved detection accuracy, thus contributing to positioning the detection target (such as a motor) more accurately.

FIG. 5 is a flowchart showing the procedure of a method for manufacturing the magnet module 10 according to the first embodiment. The method for manufacturing the magnet module 10 includes the steps S1 and S2 shown in FIG. 5. The method for manufacturing the magnet module 10 according to the first embodiment will now be described with reference to FIG. 5.

First, the manufacturer of the magnet module 10 performs the producing step S1. The producing step S1 includes letting a current flow through the coils 71, 72 in mutually opposite directions to cause the magnetic material 100 to be magnetized via the yokes 61, 62. As a result, the first magnet 1 and the second magnet 2 which are magnetized in the first direction D1 and the second direction D2 are produced as shown in FIGS. 2A-3B.

Next, the manufacturer of the magnet module 10 performs the coupling step S2. The coupling step S2 includes coupling the first magnet 1 and the second magnet 2 to each other to make the respective magnetic poles of the first magnet 1 and the second magnet 2 opposite from each other in the third direction D3 as shown in FIG. 1A. In this process step, the first magnet 1 and the second magnet 2 are coupled to each other via magnetic suction force produced between the first magnet 1 and the second magnet 2.

### (5) Advantages

In the magnet module 10 according to the first embodiment, the first magnet 1 and the second magnet 2 are coupled to each other in the third direction D3 to have mutually different magnetization directions. This may reduce, in the third direction D3, the neutral zone 102 to be produced between the first magnet 1 and the second magnet 2, thus enabling increasing a bias magnetic field to be applied by the magnet module 10 to the magnetic sensor 3. This allows the magnetic sensor 3 to have improved detection accuracy, thus contributing to positioning the detection target (such as a motor) more accurately.

In addition, in the magnet module 10 according to the first embodiment, when viewed in plan in the second direction D2, the width of the second neutral zone 102 provided between the first magnet 1 and the second magnet 2 is narrower than the width W1 of the first neutral zone 101 in each of the first magnet 1 and the second magnet 2. This may increase the bias magnetic field, compared to a situation where the width of the first neutral zone is equal to the width of the second neutral zone.

Furthermore, in the magnet module 10 according to the first embodiment, the first magnet 1 and the second magnet 2 are bias magnets for generating a bias magnetic field with respect to the magnetic sensor 3, thus enabling improving the detection accuracy of the magnetic sensor 3.

### (6) Variations

Note that the first embodiment described above is only an exemplary one of various embodiments of the present disclosure and should not be construed as limiting. Rather, the first embodiment may be readily modified in various manners depending on a design choice or any other factor without departing from the scope of the present disclosure. Next, variations of the first embodiment will be enumerated one after another. Note that the variations to be described below may be adopted in combination as appropriate.

In the first embodiment described above, the second neutral zone 102 produced between the first magnet 1 and the second magnet 2 has a width of 0 mm. However, this is only an example and should not be construed as limiting. The width of the second neutral zone 102 does not have to be 0 mm but may also be greater than 0 mm as long as the width of the second neutral zone 102 is narrower than the width W1 of the first neutral zone 101 produced in each of the first magnet 1 and the second magnet 2.

In the first embodiment described above, the magnet module 10 is a bias magnet. However, this is only an example and should not be construed as limiting. The magnet module 10 does not have to be a bias magnet but may also be a drive magnet for driving a target (such as a lens).

### Second Embodiment

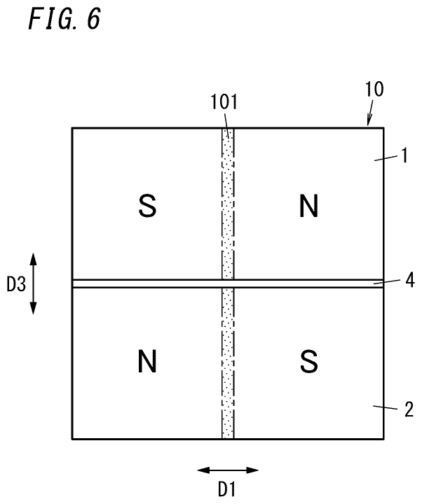

Next, a magnet module 10 according to a second embodiment will be described with reference to FIG. 6. In the following description, any constituent element of the magnet module 10 according to the second embodiment, having the same function as a counterpart of the magnet module 10 (refer to FIGS. 1A and 1B) according to the first embodiment described above, will be designated by the same reference numeral as that counterpart's, and description thereof will be omitted herein.

The magnet module 10 according to the second embodiment further includes a bonding member 4 for bonding the first magnet 1 and the second magnet 2 together, which is a difference from the magnet module 10 according to the first embodiment.

The magnet module 10 according to the second embodiment includes the first magnet 1 and the second magnet 2 as shown in FIG. 6. In addition, the magnet module 10 according to the second embodiment further includes a bonding member 4.

The bonding member 4 may include, for example, an epoxy resin. As shown in FIG. 6, the bonding member 4 is applied onto an end surface, facing the second magnet 2, of the first magnet 1 and/or an end surface, facing the first magnet 1, of the second magnet 2. Then, heating the first magnet 1 and the second magnet 2 that have been coupled to each other causes the bonding member 4 to be thermally cured, thereby bonding the first magnet 1 and the second magnet 2 together. That is to say, the bonding member 4 is a member for bonding the first magnet 1 and the second magnet 2 together. In this case, the width (i.e., a dimension as measured in the third direction D3) of the bonding member 4 is preferably less than the width (i.e., a dimension as measured in the first direction D1) of the first neutral zone 101.

In the magnet module 10 according to the second embodiment, the first magnet 1 and the second magnet 2 are coupled to each other via the bonding member 4. This contributes to reducing the size compared to a situation where the first magnet 1 and the second magnet 2 are covered with a resin member 5 (to be described later). In addition, this allows the first magnet 1 and the second magnet 2 to be coupled to each other more firmly than in a situation where the first magnet 1 and the second magnet 2 are coupled to each other via only the magnetic suction force produced between the first magnet 1 and the second magnet 2.

Note that the bonding member 4 does not have to include an epoxy resin but may also include a silicone resin, for example. Even in that case, the bonding member 4 may also be thermally cured by heating, thus allowing the first magnet 1 and the second magnet 2 to be bonded together.

Note that the various configurations (including variations) that have been described for the second embodiment may be adopted as appropriate in combination with the various configurations (including variations) that have already been described for the first embodiment.

### Third Embodiment

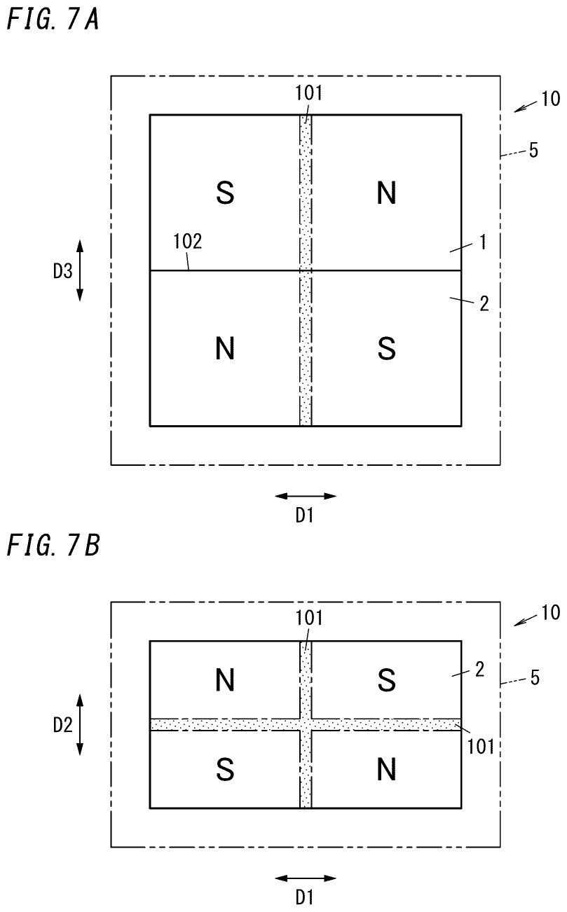

Next, a magnet module 10 according to a third embodiment will be described with reference to FIGS. 7A and 7B. In the following description, any constituent element of the magnet module 10 according to the third embodiment, having the same function as a counterpart of the magnet module 10 (refer to FIGS. 1A and 1B) according to the first embodiment described above, will be designated by the same reference numeral as that counterpart's, and description thereof will be omitted herein.

In the magnet module 10 according to the third embodiment, the first magnet 1 and the second magnet 2 are covered with a resin member 5, which is a difference from the magnet module 10 according to the first embodiment.

The magnet module 10 according to the third embodiment includes the first magnet 1 and the second magnet 2 as shown in FIGS. 7A and 7B. In addition, the magnet module 10 according to the third embodiment further includes the resin member 5 (magnet-covering resin member).

A material for the resin member 5 may be, for example, an epoxy resin. In the third embodiment, the magnet module 10 may be formed by transfer molding, for example. That is to say, the resin member 5 covers the first magnet 1 and the second magnet 2.

In the third embodiment, the first magnet 1 and the second magnet 2 may be coupled to each other either via only the magnetic force produced between the first magnet 1 and the second magnet 2 or via the bonding member 4 (refer to FIG. 6) described above, whichever is appropriate.

The magnet module 10 according to the third embodiment, as well as the magnet module 10 according to the first embodiment described above, may also reduce the neutral zone 102 to be produced between the first magnet 1 and the second magnet 2, thus enabling increasing a bias magnetic field to be applied to the magnetic sensor 3. This allows the magnetic sensor 3 to have improved detection accuracy, thus contributing to positioning the detection target (such as a motor) more accurately.

In addition, the first magnet 1 and the second magnet 2 are covered with the resin member 5, and therefore, may be protected.

Note that the resin member 5 does not have to be formed by transfer molding using an epoxy resin but may also be formed by injection molding using a polyphenylene sulfide resin, a polybutylene terephthalate resin, or a liquid crystal polymer.

Note that the various configurations (including variations) that have been described for the third embodiment may be adopted as appropriate in combination with the various configurations (including variations) that have already been described for the first and second embodiments.

### Fourth Embodiment

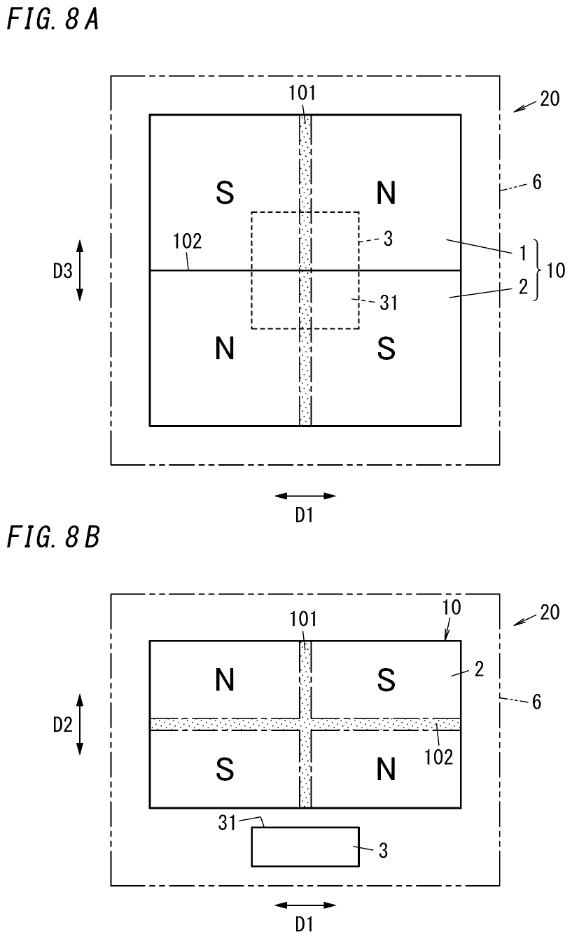

Next, a sensor module 20 according to a fourth embodiment will be described with reference to FIGS. 8A and 8B. In the following description, any constituent element of the sensor module 20 according to the fourth embodiment, having the same function as a counterpart of the magnet module 10 (refer to FIGS. 1A and 1B) according to the first embodiment described above, will be designated by the same reference numeral as that counterpart's, and description thereof will be omitted herein.

The sensor module 20 according to the fourth embodiment has an integrated structure in which the magnet module 10 and the magnetic sensor 3 are covered with a resin member 6 as shown in FIGS. 8A and 8B, which is a difference from the magnet module 10 (refer to FIGS. 1A and 1B) according to the first embodiment provided separately from the magnetic sensor 3.

A sensor module 20 according to the fourth embodiment includes the magnet module 10, the magnetic sensor 3, and the resin member 6 (sensor-covering resin member) as shown in FIGS. 8A and 8B.

A material for the resin member 6 may be, for example, an epoxy resin. In the fourth embodiment, the sensor module 20 may be formed by transfer molding, for example. That is to say, the resin member 6 covers the magnet module 10 and the magnetic sensor 3.

In the fourth embodiment, the first magnet 1 and the second magnet 2 may be coupled to each other either via only the magnetic force produced between the first magnet 1 and the second magnet 2 or via the bonding member 4 (refer to FIG. 6), whichever is appropriate.

The sensor module 20 according to the fourth embodiment has an integrated structure in which the magnet module 10 and the magnetic sensor 3 are covered with the resin member 6 and the magnet module 10 and the magnetic sensor 3 are arranged in line in the second direction D2. In addition, in the sensor module 20 according to the fourth embodiment, a surface, facing the magnet module 10 (i.e., an upper surface in FIG. 8B), of the magnetic sensor 3 is a magnetically sensitive surface 31.

The sensor module 20 according to the fourth embodiment includes the magnet module 10, and therefore, may also reduce the neutral zone 102 to be produced between the first magnet 1 and the second magnet 2, thus enabling increasing a bias magnetic field to be applied to the magnetic sensor 3. This allows the magnetic sensor 3 to have improved detection accuracy, thus contributing to positioning the detection target (such as a motor) more accurately.

Furthermore, the magnet module 10 and the magnetic sensor 3 are covered with the resin member 6, and therefore, may be protected.

Besides, the magnet module 10 and the magnetic sensor 3 are positioned by the resin member 6, thus reducing the misalignment of the magnet module 10 with respect to the magnetic sensor 3.

Note that the resin member 6 does not have to be formed by transfer molding using an epoxy resin but may also be formed by injection molding using a polyphenylene sulfide resin, a polybutylene terephthalate resin, or a liquid crystal polymer.

Note that the various configurations (including variations) that have been described for the fourth embodiment may be adopted as appropriate in combination with the various configurations (including variations) that have already been described for the first to third embodiments. cl Aspects

The foregoing description provides specific implementations of the following aspects of the present disclosure.

A magnet module (10) according to a first aspect is designed for use in a magnetic sensor (3). The magnetic sensor (3) outputs a signal representing a detected magnetic field. The magnet module (10) includes a first magnet (1) and a second magnet (2). The first magnet (1) and the second magnet (2) are both magnetized in a first direction (D1) and a second direction (D2). The second direction (D2) is perpendicular to the first direction (D1). The first magnet (1) and the second magnet (2) are provided separately and coupled to each other in a third direction (D3) to have mutually different magnetization directions. The third direction (D3) is perpendicular to the first direction (D1) and the second direction (D2).

This aspect may reduce, in the third direction (D3), a neutral zone (102) to be produced between the first magnet (1) and the second magnet (2), thus enabling increasing a bias magnetic field to be applied by the magnet module (10) to the magnetic sensor (3). This allows the magnetic sensor (3) to have improved detection accuracy, thus contributing to positioning the detection target (such as a motor) more accurately.

In a magnet module (10) according to a second aspect, which may be implemented in conjunction with the first aspect, when viewed in plan in the second direction (D2), a width of a neutral zone (102) between the first magnet (1) and the second magnet (2) is narrower than a width (W1) of a neutral zone (101) in each of the first and second magnets (1, 2).

This aspect may increase the bias magnetic field to be applied to the magnetic sensor (3), compared to a situation where the width of the neutral zone (102) is equal to the width (W1) of the neutral zone (101).

In a magnet module (10) according to a third aspect, which may be implemented in conjunction with the first or second aspect, the first magnet (1) and the second magnet (2) generate a bias magnetic field with respect to the magnetic sensor (3).

This aspect allows the magnetic sensor (3) to have improved detection accuracy.

A magnet module (10) according to a fourth aspect, which may be implemented in conjunction with any one of the first to third aspects, further includes a bonding member (4). The bonding member (4) bonds the first magnet (1) and the second magnet (2) together.

This aspect contributes to reducing the size of the magnet module (10).

In a magnet module (10) according to a fifth aspect, which may be implemented in conjunction with the fourth aspect, the bonding member (4) includes either an epoxy resin or a silicone resin.

This aspect achieves the advantage of making the bonding member (4) easily handleable.

A magnet module (10) according to a sixth aspect, which may be implemented in conjunction with any one of the first to fifth aspects, further includes a magnet-covering resin member (5). The magnet-covering resin member (5) covers the first magnet (1) and the second magnet (2).

This aspect allows the first magnet (1) and the second magnet (2) to be not only fixed firmly but also protected as well.

In a magnet module (10) according to a seventh aspect, which may be implemented in conjunction with any one of the first to sixth aspects, the magnet module (10) has a dimension (X1) equal to or less than 5 mm as measured in the first direction (D1) and a dimension (X2) equal to or less than 5 mm as measured in the third direction (D3).

This aspect contributes to reducing the size of the magnet module (10).

A sensor module (20) according to an eighth aspect includes: the magnet module (10) according to any one of the first to seventh aspects; the magnetic sensor (3); and a sensor-covering resin member (6). The sensor-covering resin member (6) covers the magnet module (10) and the magnetic sensor (3).

This aspect enables not only protecting the magnet module (10) and the magnetic sensor (3) but also reducing misalignment of the magnet module (10) with respect to the magnetic sensor (3).

A method for manufacturing a magnet module (10) according to a ninth aspect is method for manufacturing a magnet module (10) for use in a magnetic sensor (3). The magnetic sensor (3) outputs a signal representing a detected magnetic field. The method for manufacturing the magnet module (10) includes a producing step (S1) and a coupling step (S2). The producing step (S1) includes producing a first magnet (1) and a second magnet (2) by magnetizing a magnetic material (100) in a first direction (D1) and a second direction (D2). The second direction (D2) is perpendicular to the first direction (D1). The coupling step (S2) includes coupling the first magnet (1) and the second magnet (2) to each other in a third direction (D3) to cause the first magnet (1) and the second magnet (2) to have mutually different magnetization directions. The third direction (D3) is perpendicular to both the first direction (D1) and the second direction (D2).

This aspect may reduce, in the third direction (D3), a neutral zone (102) to be produced between the first magnet (1) and the second magnet (2), thus enabling increasing a bias magnetic field to be applied by the magnet module (10) to the magnetic sensor (3). This allows the magnetic sensor (3) to have improved detection accuracy, thus contributing to positioning the detection target (such as a motor) more accurately.

Note that the constituent elements according to the second to seventh aspects are not essential constituent elements for the magnet module (10) but may be omitted as appropriate.

### REFERENCE SIGNS LIST

1 First Magnet
2 Second Magnet
3 Magnetic Sensor
4 Bonding Member
5 Resin Member (Magnet-Covering Resin Member)
6 Resin Member (Sensor-Covering Resin Member)
10 Magnet Module
20 Sensor Module
100 Magnetic Material
101 First Neutral Zone (Neutral Zone)
102 Second Neutral Zone (Neutral Zone)
D1 First Direction
D2 Second Direction
D3 Third Direction
X1, X2 Dimension
S1 Producing Step
S2 Coupling step
W1 Width

1. A magnet module for use in a magnetic sensor, the magnetic sensor being configured to output a signal representing a detected magnetic field, the magnet module comprising
a first magnet and a second magnet, both of the first magnet and the second magnet being magnetized in a first direction and a second direction, the second direction being perpendicular to the first direction,
the first magnet and the second magnet being provided separately and coupled to each other in a third direction to have mutually different magnetization directions, the third direction being perpendicular to the first direction and the second direction.

2. The magnet module of claim 1, wherein
when viewed in plan in the second direction, a width of a neutral zone between the first magnet and the second magnet is narrower than a width of a neutral zone in each of the first and second magnets.

3. The magnet module of claim 1, wherein
the first magnet and the second magnet are configured to generate a bias magnetic field with respect to the magnetic sensor.

4. The magnet module of claim 1, comprising a bonding member bonding the first magnet and the second magnet together.

5. The magnet module of claim 4, wherein
the bonding member includes either an epoxy resin or a silicone resin.

6. The magnet module of claim 1, further comprising a magnet-covering resin member covering the first magnet and the second magnet.

7. The magnet module of claim 1, wherein
the magnet module has a dimension equal to or less than 5 mm as measured in the first direction and a dimension equal to or less than 5 mm as measured in the third direction.

8. A sensor module comprising:
the magnet module of claim 1;
the magnetic sensor; and
a sensor-covering resin member covering the magnet module and the magnetic sensor.

9. A method for manufacturing a magnet module for use in a magnetic sensor, the magnetic sensor being configured to output a signal representing a detected magnetic field, the method comprising:
a producing step including producing a first magnet and a second magnet by magnetizing a magnetic material in a first direction and a second direction, the second direction being perpendicular to the first direction; and
a coupling step including coupling the first magnet and the second magnet to each other in a third direction to cause the first magnet and the second magnet to have mutually different magnetization directions, the third direction being perpendicular to both the first direction and the second direction.
